(19) United States
(12) Patent Application Publication
(10) Pub. No.: US 2025/0111991 A1
(43) Pub. Date: Apr. 3, 2025

(54) TRANS-INDUCTANCE VOLTAGE REGULATORS AND TRANSFORMER ASSEMBLIES

(71) Applicant: Infineon Technologies Austria AG, Villach (AT)

(72) Inventors: Luca Peluso, Villach (AT); Roberto RIZZOLATTI, Villach (AT); Gerald J. DEBOY, Klagenfurt (AT)

(21) Appl. No.: 18/374,213

(22) Filed: Sep. 28, 2023

(51) Int. Cl. H01F 30/10; H01F 27/28; H02M 3/155; H05K 1/18

(52) U.S. Cl. CPC H01F 30/10; H01F 27/2885; H02M 3/155; H05K 1/18; H05K 2201/1003; H05K 2201/10522

(57) ABSTRACT

A power converter assembly may include multiple electrically conductive paths such as a first electrically conductive path, a second electrically conductive path, and a third electrically conductive path. The first electrically conductive path extends through first magnetically permeable material; the second electrically conductive path extending through second magnetically permeable material. The third electrically conductive path extends through both the first magnetically permeable material and the second magnetically permeable material. For example, the first electrically conductive path may be disposed alongside and in parallel with a first portion of the third electrically conductive path in the first magnetically permeable material; the second electrically conductive path may be disposed alongside and in parallel with a second portion of the third electrically conductive path in the second magnetically permeable material.

### BACKGROUND

A printed circuit board (PCB) or printed wiring board is a laminated structure of conductive layers separated by insulating layers. In general, PCBs have two functions. The first is to secure electronic components at designated locations on the outer layers of the PCB by means of affixing such as soldering. The electronic circuit instantiated by the populated circuit board is designed to provide one or more specific functions. After fabrication, the electronic circuit is powered to perform the desired functions.

Typically, a printed circuit board is a planar device on which multiple components are interconnected via traces to provide the functions as previously discussed. Such implementations of fabricating circuitry on a planar circuit board assembly is dimensionally limited, preventing high density implementation of circuitry.

Modern VR (Voltage Regulator) modules for high power demanding applications (such as AI training processors and TPU based data-centers) can be distinguished in two categories based on the way the heat generated by the semiconductor devices is sank out of the module towards the heatsink.

Conventional power stage cooled modules include physical stack-up of components, enabling a direct contact between the power stage itself (such as including a set of semiconductor devices and the package embedding it) and the heatsink which is the most effective way to sink the generated heat out and therefore leading to a very low Rth (thermal resistance, the lower the better).

It is further noted that a conventional TLVR (Trans-inductance Voltage Regulator) system is generally a voltage regulator (e.g. a buck converter) where the magnetic device is no longer a single-winding inductor, but a transformer with two windings; where the primary windings constitute the phase inductors. The secondary windings are the so called TLVR windings, which are used to improve the transient performance. The secondary windings of each phase are series connected and their routing with respect to a PCB (Printed Circuit Board) ensures that the transformer dots rule is always fulfilled.

### BRIEF DESCRIPTION

Implementation of clean energy (or green technology) is very important to reduce our impact as humans on the environment. In general, clean energy includes any evolving methods and materials to reduce an overall toxicity of energy consumption on the environment.

This disclosure includes the observation that raw energy, such as received from green energy sources or non-green energy sources, typically needs to be converted into an appropriate form (such as desired AC voltage, DC voltage, etc.) before it can be used to power end devices such as servers, computers, mobile communication devices, etc. Regardless of whether energy is received from green energy sources or non-green energy sources, it is desirable to make most efficient use of raw energy provided by such systems to reduce our impact on the environment. This disclosure contributes to reducing our carbon footprint (and green energy) via more efficient energy conversion and circuit implementations supporting same.

As discussed herein, a fabricator produces one or more assemblies to provide higher density circuitry and better heatsink capability than provided by conventional instantiation of circuitry on planar circuit boards.

More specifically, this disclosure includes an apparatus, systems, methods, etc. For example, an apparatus as discussed herein includes: a first electrically conductive path extending through first magnetically permeable material; and a second electrically conductive path extending through the first magnetically permeable material, the first electrically conductive path disposed alongside and in parallel with the second electrically conductive path through the first magnetically permeable material.

The apparatus further includes an assembly. The assembly and be configured to include: the first electrically conductive path; the second electrically conductive path; a first substrate. A first axial end of the first electrically conductive path is directly coupled to a first node of the first substrate, the first electrically conductive path providing a first heat dissipation path between a second axial end of the first electrically conductive path and the first node. A first axial end of the second electrically conductive path is directly coupled to a second node of the first substrate, the second electrically conductive path providing a second heat dissipation path between a second axial end of the second electrically conductive path and the second node. An axial length of the first electrically conductive path extends substantially orthogonal to a planar surface of the first substrate. An axial length of the second electrically conductive path extends substantially orthogonal to the planar surface of the first substrate. The apparatus can be configured to include electronic circuitry embedded in the first substrate. The electronic circuitry can be configured to control conveyance of current through the first electrically conductive path. Additionally, or alternatively, the electronic circuitry may be affixed to the first substrate. Such electronic circuitry can be configured to control conveyance of current through the first electrically conductive path.

Further, the assembly can be configured to include: a third electrically conductive path extending through second magnetically permeable material; a fourth electrically conductive path extending through the second magnetically permeable material, the third electrically conductive path disposed alongside and in parallel with the fourth electrically conductive path through the second magnetically permeable material. A first axial end of the third electrically conductive path is directly coupled to a third node of the first substrate, the third electrically conductive path providing a third heat dissipation path between a second axial end of the third electrically conductive path and the third node; a first axial end of the fourth electrically conductive path may be directly coupled to a fourth node of the first substrate, the fourth electrically conductive path providing a fourth heat dissipation path between a second axial end of the fourth electrically conductive path and the fourth node; an axial length of the third electrically conductive path be configured to extend substantially orthogonal to the planar surface of the first substrate; and an axial length of the fourth electrically conductive path can be configured to extend substantially orthogonal to the planar surface of the first substrate.

Still further, the apparatus as discussed herein can be configured to include: an electrically conductive element providing connectivity between the second node and the fourth node, the electrically conductive element connecting the second electrically conductive path and the fourth electrically conductive path in series. The electrically conductive element may be affixed to the first substrate.

Further examples as discussed herein include a first assembly and the second assembly. The first assembly configured to include: a first substrate; the first electrically conductive path; the second electrically conductive path. A first axial end of the first electrically conductive path may be directly coupled to a first node of the first substrate, the first electrically conductive path providing a first heat dissipation path between a second axial end of the first electrically conductive path and the first node; a first axial end of the second electrically conductive path may be directly coupled to a second node of the first substrate, the second electrically conductive path providing a second heat dissipation path between a second axial end of the second electrically conductive path and the second node. An axial length of the first electrically conductive path can be configured to extend substantially orthogonal to a planar surface of the first substrate; and an axial length of the second electrically conductive path can be configured to extend substantially orthogonal to the planar surface of the first substrate. The second assembly can be configured to include: a second substrate; a third electrically conductive path extending through second magnetically permeable material; a fourth electrically conductive path extending through the second magnetically permeable material, the third electrically conductive path disposed alongside and in parallel with the fourth electrically conductive path through the second magnetically permeable material. A first axial end of the third electrically conductive path may be directly coupled to a first node of the second substrate, the third electrically conductive path providing a third heat dissipation path between a second axial end of the third electrically conductive path and the first node of the second substrate; a first axial end of the fourth electrically conductive path may be directly coupled to a second node of the second substrate, the fourth electrically conductive path providing a fourth heat dissipation path between a second axial end of the fourth electrically conductive path and the second node of the second substrate. An axial length of the third electrically conductive path can be configured to extend substantially orthogonal to a planar surface of the second substrate; and an axial length of the fourth electrically conductive path can be configured to extend substantially orthogonal to the planar surface of the second substrate. Still further, the apparatus can be configured to include a third substrate. The first substrate and the second substrate may be affixed to the third substrate. The apparatus further may be configured to include an electrically conductive element providing serial connectivity of the second electrically conductive path and the fourth electrically conductive path; the electrically conductive element may be affixed to the third substrate.

Additionally, this disclosure includes an apparatus comprising: a first electrically conductive path extending through first magnetically permeable material; a second electrically conductive path extending through second magnetically permeable material; and a third electrically conductive path extending through both the first magnetically permeable material and the second magnetically permeable material, the first electrically conductive path disposed alongside and in parallel with a first portion of the third electrically conductive path in the first magnetically permeable material, the second electrically conductive path disposed alongside and in parallel with a second portion of the third electrically conductive path in the second magnetically permeable material. In one example, the first magnetically permeable material and the second magnetically permeable material are disposed together in a single homogeneous block of magnetically permeable material.

A combination of the first electrically conductive path and the first portion of the third electrically conductive path may be a first transformer in which the first electrically conductive path is inductively coupled to the first portion of the third electrically conductive path; a combination of the second electrically conductive path and the second portion of the third electrically conductive path may be a second transformer in which the second electrically conductive path is inductively coupled to the second portion of the third electrically conductive path. The first magnetically permeable material may be absent from a first volume between the first electrically conductive path and the first portion of the third electrically conductive path; the second magnetically permeable material may be absent from a second volume between the second electrically conductive path and the second portion of the third electrically conductive path.

The apparatus can be configured to include: i) first switch circuitry coupled to a first axial end of the first electrically conductive path, the first switch circuitry operative to control a magnitude of first current through the first electrically conductive path; and ii) second switch circuitry coupled to a first axial end of the second electrically conductive path, the second switch circuitry operative to control a magnitude of second current through the second electrically conductive path. Control of the first switch circuitry is operative to produce a first output current outputted from a second axial end of the first electrically conductive path; control of the second circuitry is operative to produce a second output current outputted from a second axial end of the second electrically conductive path. The second axial end of the first electrically conductive path may be directly connected to the second axial end of the second electrically conductive path to collectively produce an output voltage.

Still further, the third electrically conductive path may be configured to convey only alternating current via control of switches.

Yet further, a first axial end of the third electrically conductive path and a second axial end of the third electrically conductive path may be both directly coupled to a voltage reference.

The apparatus as discussed herein may include a substrate; a first axial end of the first electrically conductive path being directly coupled to a first node of the substrate, the first electrically conductive path providing a first heat dissipation path between a second axial end of the first electrically conductive path and the first node; and a first axial end of the second electrically conductive path being directly coupled to a second node of the substrate, the second electrically conductive path providing a second heat dissipation path between a second axial end of the second electrically conductive path and the second node. An axial length of the first electrically conductive path may extend substantially orthogonal to a planar surface of the substrate; and an axial length of the second electrically conductive path may extend substantially orthogonal to the planar surface of the substrate.

As a yet further example, the apparatus as discussed herein can be configured to include a first substrate and a second substrate. A first axial end of the first electrically conductive path may be directly coupled to a first node of the first substrate, the first electrically conductive path operative to provide a first heat dissipation path between a second axial end of the first second electrically conductive path and the first node. A first axial end of the second electrically conductive path being directly coupled to a second node of the second substrate, the second electrically conductive path operative to provide a second heat dissipation path between a second axial end of the second electrically conductive path and the second node. An axial length of the first electrically conductive path can be configured to extend substantially orthogonal to a planar surface of the first substrate; and an axial length of the second electrically conductive path can be configured to extend substantially orthogonal to a planar surface of the second substrate.

The apparatus as discussed herein may include: i) a first conductor element extending between the second axial end of the first electrically conductive path to a third node of the substrate, the first conductor element operative to convey first output current from the second axial end of the first electrically conductive path to the substrate; and ii) a second conductor element extending between the second axial end of the second electrically conductive path to a fourth node of the substrate, the second conductor element operative to convey second output current from the second axial end of the second electrically conductive path to the substrate.

Note that the third electrically conductive path may be implemented as a series circuit path disposed in a trans-inductance voltage regulator.

Yet further, the apparatus as discussed herein may include a metal layer coupled to first axial ends of the first electrically conductive path and the second electrically conductive path. A portion of the first magnetically permeable material and a portion of the second magnetically permeable material may be disposed between the metal layer and a substrate to which second axial ends of the first electrically conductive path and the second electrically conductive path are coupled. The metal layer is operative to provide electromagnetic shielding of noise emitted by a first return electrically conductive path extending from an axial end of the first portion of the third electrically conductive path to the substrate; and the metal layer is operative to provide electromagnetic shielding of noise emitted by a second return electrically conductive path extending from an axial end of the second portion of the third electrically conductive path to the substrate.

In accordance with further examples, the apparatus as discussed herein may include: a metal shield layer enveloping a third portion of the third electrically conductive path, the third portion of the third electrically conductive path neither disposed in the first magnetically permeable material nor disposed in the second magnetically permeable material.

The apparatus as discussed herein may include an interposer operative to provide connectivity of the first portion of the third electrically conductive path to the second portion of the third electrically conductive path; the interposer may be disposed between a host substrate and a combination of the first magnetically permeable material and the second magnetically permeable material.

Note further that the first magnetically permeable material, the second magnetically permeable material, the first electrically conductive path, the second electrically conductive path, the first portion of the third electrically conductive path, and the second portion of the third electrically conductive path may be disposed in an over-mold assembly.

Yet further, the apparatus as discussed herein may include an over-mold assembly including a first circuit board, the first magnetically permeable material, the second magnetically permeable material, the first electrically conductive path and the second electrically conductive path. The over-mold assembly can be configured to reside between a second circuit board and a third circuit board, the first circuit board operative to provide connectivity between the second circuit board and the third circuit board.

In accordance with further examples, the apparatus as discussed herein may include an assembly including the first magnetically permeable material and the second magnetically permeable material is operative to reside between a first circuit board and a second circuit board, a third portion of the third electrically conductive path may be disposed between the assembly and the second circuit board.

A third portion of the third electrically conductive path can be configured to reside between the first magnetically permeable material and the second magnetically permeable material. The third portion of the third electrically conductive path may be a return path form an axial end of the first portion of the third electrically conductive path to the substrate.

As a further example, an apparatus as discussed herein includes: a first electrically conductive path extending through first magnetically permeable material; and a second electrically conductive path extending through the first magnetically permeable material, the first electrically conductive path disposed alongside and in parallel with the second electrically conductive path in the first magnetically permeable material.

Additionally, note that although each of the different features, techniques, configurations, etc., herein may be discussed in different places of this disclosure, it is intended, where suitable, that each of the concepts can optionally be executed independently of each other or in combination with each other. Accordingly, the one or more present inventions as described herein can be embodied and viewed in many different ways.

Also, note that this preliminary discussion of techniques herein (BRIEF DESCRIPTION) purposefully does not specify every novel aspect of the present disclosure or claimed invention(s). Instead, this brief description only presents general aspects and corresponding points of novelty over conventional techniques. For additional details and/or possible perspectives (permutations) of the invention(s), the reader is directed to the Detailed Description section (which is a summary) and corresponding figures of the present disclosure as further discussed below.

### BRIEF DESCRIPTION OF THE DRAWINGS

FIG. 1A is an example 3-Dimensional (3-D) diagram illustrating a transformer or power converter assembly as discussed herein.

FIG. 1B is an example side view diagram illustrating a transformer or power converter assembly as discussed herein.

FIG. 2 is an example diagram illustrating a trans-inductance voltage regulator circuit as discussed herein.

FIG. 3A is an example diagram illustrating a side cutaway view of a first transformer assembly as discussed herein.

FIG. 3B is an example diagram illustrating a side cutaway view of a second transformer assembly as discussed herein.

FIG. 4 is an example 3-D diagram illustrating a power converter assembly including multiple power converter phases as discussed herein.

FIG. 5 is an example diagram illustrating a side cutaway view of a transformer assembly as discussed herein.

FIGS. 6A and 6B are example diagrams illustrating a side cutaway view of a transformer assembly as discussed herein.

FIG. 7 is an example diagram illustrating of a power stage and TLVR (trans-inductance voltage regulator) connection as discussed herein.

FIG. 8 is an example 3-D diagram illustrating a power converter assembly illustrating flow of current through a series connection of multiple transformer windings as discussed herein.

FIG. 9 is an example side view diagram illustrating implementation of a transformer assembly as discussed herein.

FIG. 10A and FIG. 10B are example cross-section view diagrams illustrating inductive winding associated with a transformer assembly as discussed herein.

FIG. 11 is an example diagram illustrating a power supply circuit for implementing any of the transformer assemblies in a trans-inductance voltage regulator as discussed herein.

FIG. 12 is an example diagram illustrating different views of a transformer assembly as discussed herein.

FIG. 13 is an example diagram illustrating different views of a transformer assembly as discussed herein.

FIG. 14 is an example diagram illustrating different views of a transformer assembly as discussed herein.

FIG. 15 is an example diagram illustrating an over-mold transformer assembly as discussed herein.

FIG. 16 is an example diagram illustrating different views of a transformer assembly as discussed herein.

FIGS. 17A, 17B, and 17C are example diagrams illustrating different views of providing serial connecting through multiple windings of multiple transformers as discussed herein.

FIG. 18A is an example diagram of multiple individual assemblies mounted on a respective host substrate as discussed herein.

FIG. 18B is an example diagram of the multiple instances of multiple sub-assemblies forming a single multi-phase assembly mounted on a respective host substrate as discussed herein.

The foregoing and other objects, features, and advantages of the disclosed matter herein will be apparent from the following more particular description herein, as illustrated in the accompanying drawings in which like reference characters refer to the same parts throughout the different views. The drawings are not necessarily to scale, with emphasis instead being placed upon illustrating the principles, concepts, aspects, techniques, etc.

### DETAILED DESCRIPTION

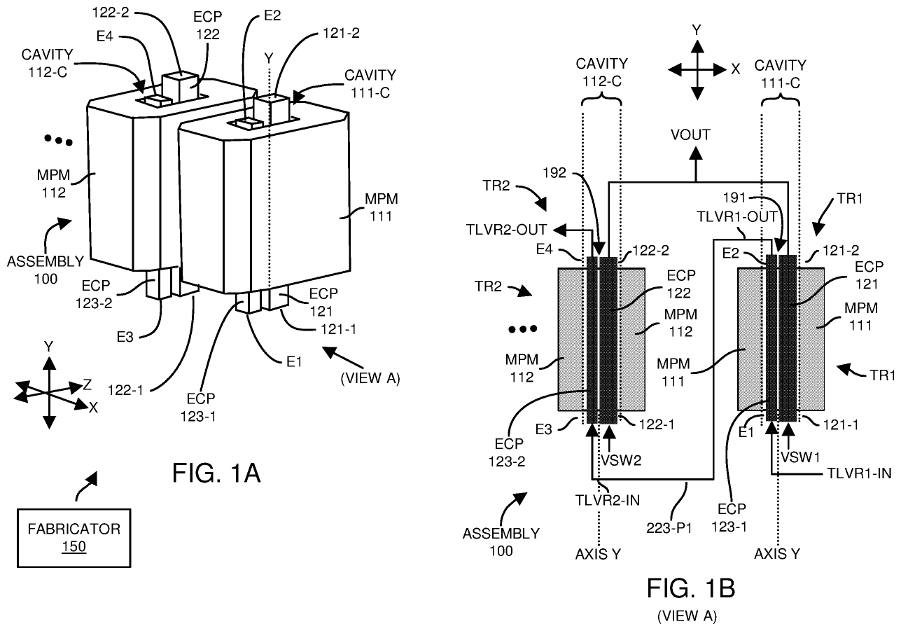

Now, more specifically, FIG. 1A is an example 3-Dimensional (3-D) diagram illustrating a power converter assembly as discussed herein.

As shown in FIG. 1A, a respective fabricator 150 or other suitable entity fabricates the assembly 100 to include one or more blocks of magnetically permeable material such as a first block of magnetically permeable material 111, a second block of magnetically permeable material 112, . . . , electrically conductive path 121, electrically conductive path 122, electrically conductive path 123-1, electrically conductive path 123-2, etc.

The magnetic permeability of magnetically permeable material 111 may be the same or different than the magnetic permeability of magnetically permeable material 112, and so on. In one example, the first magnetically permeable material 111 and the second magnetically permeable material 112 are disposed together, fused, connected, etc., as a single homogeneous block of magnetically permeable material.

Further in this example, the magnetically permeable material 111 includes cavity 111-C (opening or volume) through which both the electrically conductive path 121 and the electrically conductive path 123-1 pass from one end to the other. Each of the electrically conductive path 121 and electrically conductive path 123-1 may be coated with an insulator material or divided via an insulative spacer such that the pair of electrically conductive path 121 and electrically conductive path 123-1 are separated by an insulator layer such that the electrically conductive path 121 is electrically isolated (e.g., not touching) with respect to the electrically conductive path 123-1. In other words, magnetically permeable material 111 may be absent form between the electrically conductive path 121 and the electrically conductive path 123-1.

Yet further, each of the electrically conductive path 121 and the electrically conductive path 123-1 extend axially parallel to the Y-axis. For example, the electrically conductive path 121 includes a first axial end 121-1 protruding from the magnetically permeable material 111 and cavity 111-C; the electrically conductive path 121 includes a second axial end 121-2 protruding from the magnetically permeable material 111 and cavity 111-C. The electrically conductive path 123-1 includes a first axial end E1 protruding from the magnetically permeable material 111 and cavity 111-C; the electrically conductive path 123-1 includes a second axial end E2 protruding from the magnetically permeable material 111 and cavity 111-C.

The magnetically permeable material 112 (such as adjacent to the magnetically permeable material 111) includes cavity 112-C (open volume or space) through which electrically conductive path 122 and the electrically conductive path 123-2 pass. Each of the electrically conductive path 122 and electrically conductive path 123-2 may be coated with an insulator material or the pair of electrically conductive path 122 and electrically conductive path 123-2 are separated by an insulator layer such that the electrically conductive path 122 is electrically isolated (e.g., not touching) with respect to the electrically conductive path 123-2. In other words, magnetically permeable material 112 may be absent form between the electrically conductive path 122 and the electrically conductive path 123-2.

Yet further, each of the electrically conductive path 122 and the electrically conductive path 123-2 extend axially parallel to the Y-axis. For example, the electrically conductive path 122 includes a first axial end 122-1 protruding from the magnetically permeable material 112 and cavity 112-C; the electrically conductive path 122 includes a second axial end 122-2 protruding from the magnetically permeable material 112 and cavity 112-C. The electrically conductive path 123-2 includes a first axial end E3 protruding from the magnetically permeable material 112 and cavity 112-C; the electrically conductive path 123-2 includes a second axial end E4 protruding from the magnetically permeable material 112 and cavity 112-C.

Connectivity of the different windings (such as electrically conductive paths 121, 122, 123-1, 123-2, etc.) may vary depending on the circuit implementation.

FIG. 1B is an example side view diagram illustrating a power converter assembly as discussed herein.

The side view of the assembly 100 illustrates the spacing or open volume or mere separation between the electrically conductive path 121 and the spacing between electrically conductive path 122 and electrically conductive path 123-2. As previously discussed, the electrically conductive path 121 can be spaced from the electrically conductive path 123-1 via are respective layer of insulator material 191; the electrically conductive path 122 can be spaced from the electrically conductive path 123-2 via are respective layer of insulator material 192.

As shown this side cutaway view, the assembly 100 (such as an apparatus, power converter assembly, transformer assembly, etc.) includes: i) a first electrically conductive path 121 (such as a first inductive path) extending through first magnetically permeable material 111; ii) a second electrically conductive path 122 (such as a second inductive path) extending through second magnetically permeable material 122; and iii) a third electrically conductive path (such as combination of electrically conductive path 123-1 and electrically conductive path 123-2) extending through both the first magnetically permeable material 111 and the second magnetically permeable material 112.

The first electrically conductive path 111 is disposed alongside and in parallel with a first portion of the third electrically conductive path (such as electrically conductive path 123-1) in the first magnetically permeable material 111; the second electrically conductive path 121 is disposed alongside and in parallel with a second portion of the third electrically conductive path (such as electrically conductive path 123-2) in the second magnetically permeable material 112. Circuit path 223-P1 provides connectivity of the electrically conductive path 123-1 to the electrically conductive path 123-2 to create the overall electrically conductive path 123 (i.e., series circuit path).

In one example, a combination of the first electrically conductive path 121 and the first portion of the third electrically conductive path (a.k.a., electrically conductive path 123-1) is a first transformer TR1 in which the first electrically conductive path 121 is inductively coupled to the first portion of the third electrically conductive path (123-1); a combination of the second electrically conductive path 122 and the second portion of the third electrically conductive path (a.k.a., electrically conductive path 123-2) is a second transformer TR2 in which the second electrically conductive path 122 is inductively coupled to the second portion of the third electrically conductive path (123-2).

As previously discussed, the first magnetically permeable material 111 includes cavity 111-C in which the first magnetically permeable material 111 is absent from a first volume or space between the first electrically conductive path 121 and the first portion of the third electrically conductive path (123-1). Additionally, the second magnetically permeable material 112 includes cavity 112-C in which the second magnetically permeable material 112 is absent from a second volume or spacing between the second electrically conductive path 122 and the second portion of the third electrically conductive path (123-2).

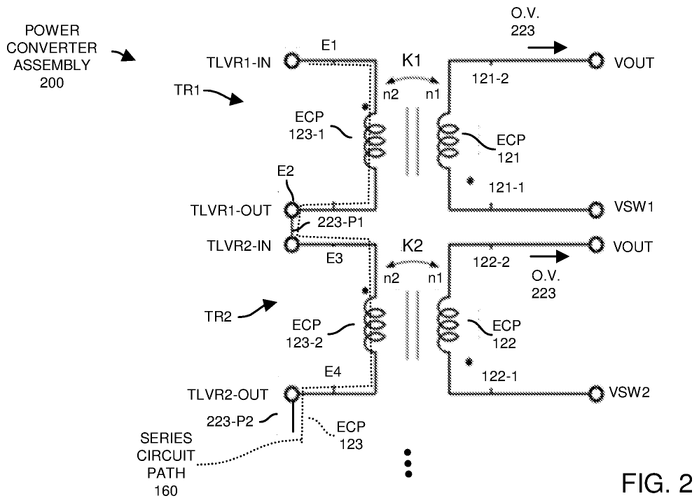

As further discussed herein, one or more instances of the assembly 100 can be implemented in a trans-inductance voltage regulator (a.k.a., as TLVR) to generate a respective output voltage 223 (see FIG. 2) via contributions of output current from each of the electrically conductive path 121 and electrically conductive path 122. In such an instance, the corresponding TLVR windings of adjacent phases are connected as shown in FIG. 1B in order to guarantee the proper coupling with each relative phase. When a positive load step happens on Vout, the current within the TLVR winding is positive from node TLVR1_in to node TLVR2_out, and vice versa. For example, during load current release (drop in output current associated with Vout) on Vout, the current is positive from node TLVR2_out to node TLVR1_in. Therefore, referring to FIG. 2, node TLVR1_out is connected to node TLVR2_in. Finally, node TLVR2_out is routed back to a respective PCB (substrate such as Printed Circuit Board) in order to guarantee the TLVR connection among adjacent modules.

FIG. 2 is an example diagram illustrating logical and physical connectivity multiple windings in a trans-inductance voltage regulator as discussed herein.

For example, as shown in a power converter assembly 200 such as a portion of a trans-inductance voltage regulator circuit, the electrically conductive path 121 (such as a first phase inductor) extends between the node VSW1 and the node VOUT (producing output voltage 223); the electrically conductive path 122 (such as a second phase inductor) extends between the node VSW2 and the node VOUT (producing output voltage 123).

The power converter 200 includes a series circuit path between node TLVR1-in and TLVR2-out. The series circuit path 160 (a.k.a., electrically conductive path 123) includes electrically conductive path 123-1 and the electrically conductive path 123-2 condition in series in which the electrically conductive path 223-P1 provides connectivity between node E2 (such as node TLVR1-OUT) and node E3 (such as node TLVR2-IN).

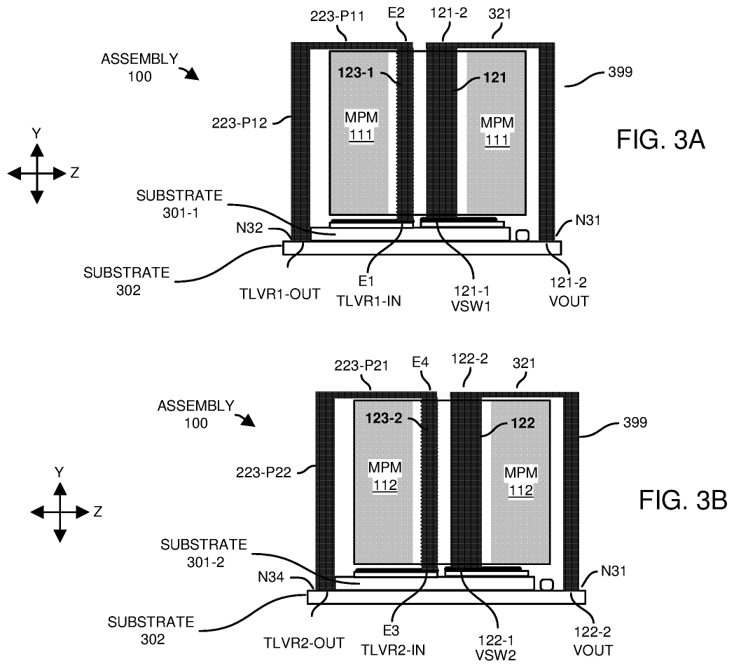

FIG. 3A is an example diagram illustrating a side cutaway view of a first transformer as discussed herein. FIG. 3B is an example diagram illustrating a side cutaway view of a first transformer as discussed herein.

In this example, the phase winding (such as electrically conductive paths as discussed herein) fulfill not only respective electrical tasks, but also act as a very effective thermal bridge to a heatsink above and/or below the assembly 100 as further discussed herein.

In this example the TLVR routing is done through a substrate 301 (substrate layer such as one or more different substrates or circuit board). Specifically, the input of each TLVR winding (such as electrically conductive path 123-1, electrically conductive path 123-2, etc.) may be connected through a copper clip to the PCB (TLVR 1/2 IN). Such copper clip (such as clip combination of electrically conductive path 223-P11 and electrically conductive path 223-P12) may touch the power stage's package such as substrate 302 or may be lifted up with respect to it. In the latter cases, a respective supplemental electrically conductive path provides connectivity of the TLVR1-in node or TLVR2-in node to the substrate 302. Similar to the Vout potential providing output voltage 223, the top end of each TLVR winding (such as electrically conductive path 121 and electrically conductive path 123-1) is routed back to the PCB (substrate 301 and/or substrate 302) through copper clips (such as clip combination of electrically conductive path 321 and electrically conductive path 399).

More specifically, the axial length of the first electrically conductive path 121 extends substantially orthogonal to a planar surface (such as in the X-Z plane) of the substrate 301 and/or substrate 302 as well as planar surface (such as in the X-Z plane) associated with electrically conductive element 321 (such as in the X-Z plane). A portion of the assembly 100 in FIG. 3A can be configured to include a first metal clip (or electrically conductive element or circuit path) providing connectivity (such as a combination of electrically conductive element 321 and electrically conductive element 399) between the node 121-2 and the node N31 to substrate 301. Additionally, the assembly 100 in FIG. 3A can be configured to include a second metal clip (or electrically conductive element or circuit path) providing connectivity (such as a combination of electrically conductive element 223-P11 on top and electrically conductive element 223-P12 on side) between the node E2 and the node N32.

Thus, examples as discussed herein include a first conductor element (such as electrically conductive element 321 and electrically conductive element 399) extending between the second axial end 121-2 of the first electrically conductive path 121 to a node N31 of the substrate 301 or substrate 302. The first conductor element or clip is operative to convey first output current from the second axial end 121-2 of the second electrically conductive path to the substrate 301 or substrate 302, providing power (such as via an output voltage 223) to a load associated with the substrate 302.

Note that the axial length of the second electrically conductive path 122 in FIG. 3B can be configured to extend substantially orthogonal to a planar surface of the substrate 301 and/or substrate 302 as well as planar surface associated with electrically conductive element 321. A portion of the assembly 100 such as a first metal clip (or electrically conductive element or circuit path) providing connectivity (such as a combination of electrically conductive element 321 and electrically conductive element 399) between the node 122-2 and the node N31. Additionally, the assembly 100 in FIG. 3B can be configured to include a third metal clip (or electrically conductive element or circuit path) providing connectivity (such as a combination of electrically conductive element 223-P21 and electrically conductive element 223-P22) between the node E4 and the node N34.

Thus, examples as discussed herein include a conductor element (such as electrically conductive element 321 and electrically conductive element 399) extending between the second axial end 121-2 of the first electrically conductive path 121 to a node N31 of the substrate 301 or substrate 302. The second conductor element is operative to convey second output current associated with the output voltage 223 from the second axial end 122-2 of the second electrically conductive path to the substrate 301 or substrate 302.

Note that the inter-winding connection (such as circuit path 223-P1 in FIG. 2) between the two adjacent TLVR windings such as from node N32 to node E3 may be achieved from TLVR1 OUT to TLVR 2 IN through internal layers of the PCB substrate (such as substrate 301 and/or substrate 302).

Given its electrical task, each of the the TLVR windings as discussed herein may be subject to a relatively high voltage (up to (Vin−Vo)*Nph) (e.g., when discrete transient inductor is used) but also fast and high current variations over time (high di/dt).

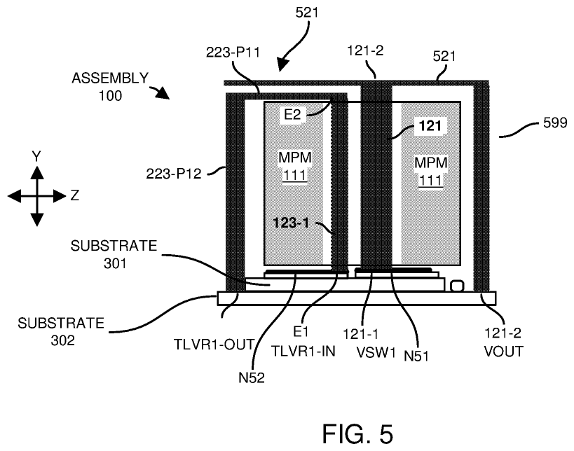

The high di/dt through the electrically conductive paths may lead the TLVR windings to be very noisy requiring it to be shielded in order to not disturb the circuitry in the vicinity. Moreover, the high voltage of the TLVR winding may bring the need that the thermal interface material which is typically placed between top surface of the module and the customer's heatsink, to be thicker than usual in order to provide sufficient electrical isolation. However, the thicker the thermal interface material (a.k.a., TIM), the higher the thermal resistance Rth and therefore the lower it's thermal dissipation capabilities. For these reasons in certain applications, it may be required or desired to shield the TLVR winding (a.k.a., electrically conductive paths) and at the same time having a stable, low potential on the top exposed surface. This can be achieved with the implementation shown in FIG. 5, where the Vout clip covers the TLVR winding and exposes only the stable and low Vout potential.

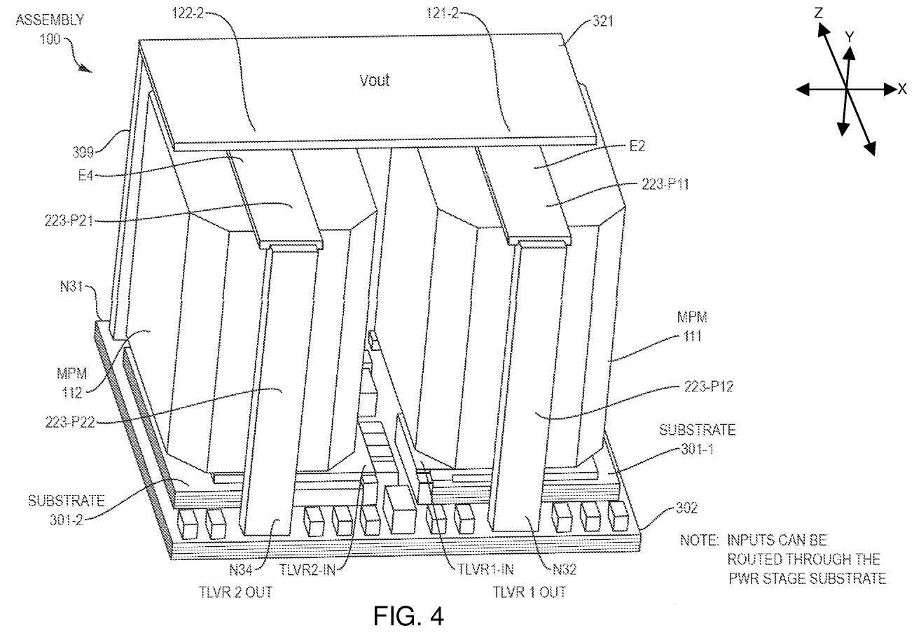

FIG. 4 is an example 3-D diagram illustrating a power converter assembly including multiple power converter phases as discussed herein.

In this example, a first clip providing connectivity includes a planar layer of metal 321 (such as in the X-Z plane as shown) as well as a planar layer of metal 399 (such as in the X-Y plane as shown) providing the conductivity between the axial ends 121-2 and 122-2 (nodes) and the node N31 associated with the substrate 302. Accordingly, the output voltage 223 (Vout) is provided to the substrate 302 via the first metal clip.

Alternatively, note that the first clip can be connected to the substrate 301-2; the substrates 301-1 and 301-2 can be configured to provide a conductive path layer to convey the output voltage Vout received from the first clip to the substrate 301 and/or substrate 302.

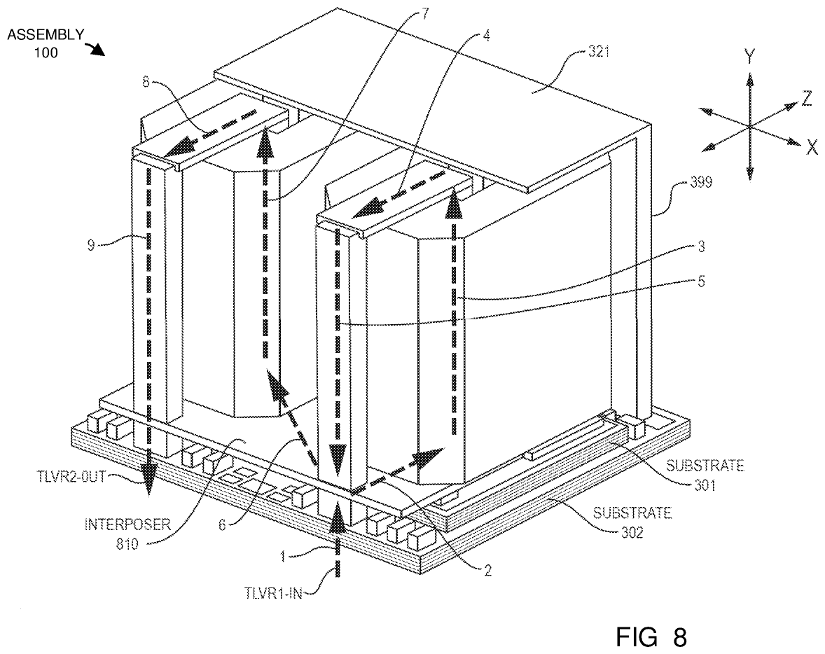

Yet further, the substrate 302 inputs the input voltage TLVR1-IN (such as any suitable reference voltage or any suitable reference potential) through a respective clip or electrically conductive path through substrate 301-1 to the node E1 of the electrically conductive path 123-1 in a manner as previously discussed. The substrate 302 provides connectivity from the node N32 (such as TLVR1_OUT) to a clip or through the substrate 301-2 to the node E3 of the electrically conductive path 123-2. An example of current associated with the electrically conductive path 123 (series circuit path 160) is shown in FIG. 8.

FIG. 5 is an example diagram illustrating a side cutaway view of a transformer assembly as discussed herein.

In yet another example, note that the high voltage and di/dt related challenges of a TLVR winding can be overcame by using a coaxial cable/block for the part of the winding disposed outside of the core. An example is shown in FIG. 5. Specifically, the inner conductor (such as shielded electrically conductive path 223-P11) provides connectivity of the output of the electrically conductive path 123-1 back to the substrate 301 and/or substrate 302 via the electrically conductive element 223-P12. In such an instance, the left portion 521-L of the planar metal layer 521 (such as stable voltage potential such as Vout or a DC voltage) overhangs the electrically conductive path 223-P11, providing EMI shielding with respect to wireless emissions from the electrically conductive path 223-P11. Thus, in addition to being a heat sink to thermal energy received from the electrically conductive path 121, the planar metal layer 521 atop the assembly 100 therefore provides shielding of noise the required shielding.

Note further that in a similar manner to the phase winding, each TLVR winding (such as electrically conductive path 123-1, 123-2, etc.) can be used to extrapolate the heat out of the power stage (such as substrate 301 and corresponding components or substrate 302 and corresponding components), boosting the assembly's 100 ability to dissipate heat.

This example of the assembly 100 can be configured to include a full shielding of the TLVR winding (such as electrically conductive path 123-1 and electrically conductive path 123-2) as shown in FIG. 5. For example, for example, electrically conductive element 521 blocks wireless noise launched from the electrically conductive element 223-P11.

As further noted in this example, the assembly 100 can be configured to include substrate 301 and/or substrate 302. A first axial end 121-1 of the first electrically conductive path 121 is directly coupled to a first node N51 of the substrate 301. In such an instance, the first electrically conductive path 121 provides a first heat dissipation path from a second axial end E2 through the first electrically conductive path 121 to the first node N51. In other words, the heat associated with the electrically conductive path 121 can be dissipated to the substrate 301 and/or substrate 302. The electrically conductive element 521 also provides heat dissipation of heat received from the electrically conductive path 121 to air above the assembly. A heatsink can be disposed atop the electrically conductive path 521.

As further shown, a first axial end 121-1 of the electrically conductive path 121 may be directly coupled to a node N51 (such as surface pad) of the substrate 301 or substrate 302, providing heatsink capability. For example, in such an instance, the electrically conductive path 121 provides a heat dissipation path from a first axial end 121-1 and node N51 through the electrically conductive path 121 to the electrically conductive path 521 or vice-versa. The electrically conductive element 521 provides heat dissipation of heat received from the electrically conductive path 121 above the assembly.

Yet further, a first axial end E1 of the electrically conductive path 123-1 may be directly coupled to a second node N52 (such as surface pad) of the substrate 301 or substrate 302, providing heatsink capability. In such an instance, the second electrically conductive path 123-1 provides a heat dissipation path from a first axial end E1 through the electrically conductive path 123-1 to the electrically conductive path 223-P11. The electrically conductive path 123-1 provides flow of heat from the substrate 301 or substrate 302 through the node N52 and electrically conductive path 123-1 to the electrically conductive path 223-P11.

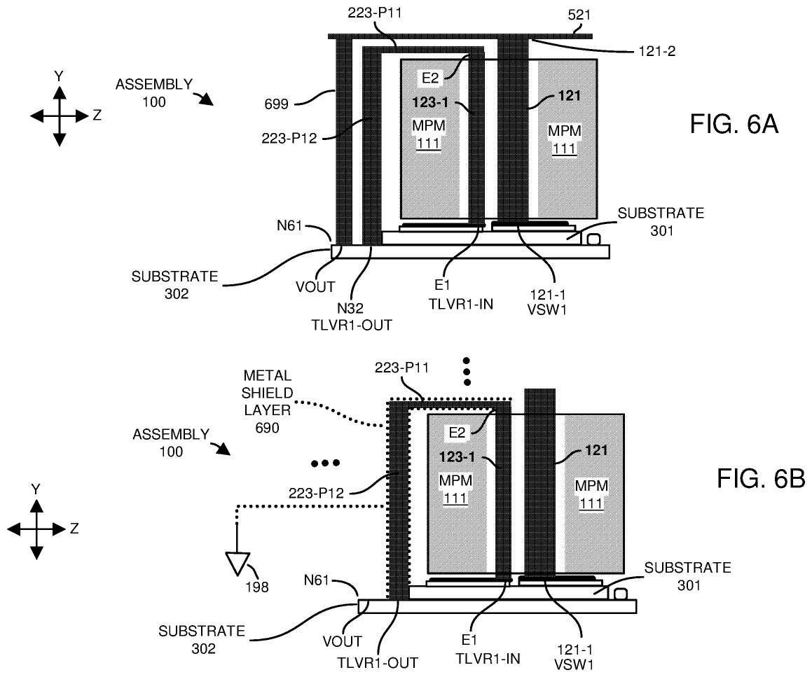

FIG. 6A is an example diagram illustrating a side cutaway view of a transformer assembly as discussed herein.

In this example, a first metal clip or return path (such as including electrically conductive path 223-P11 and electrically conductive path 223-P12) associated with electrically conductive path 123-1 can be configured to provide connectivity of axial end E2 to the node N32 coupled to substrate 301 and/or substrate 302.

As further shown, a second metal clip or return path (such as including planar metal layer 521 and planar metal layer 699) associated with the electrically conductive path 121 extends between axial end 121-2 and the node N61 of the substrate 302. Further note that a portion of the planar metal layer 521 extends to the right to provide additional heat sink capability atop the assembly 100.

Thus, planar metal layer 521 may be a heatsink. The combination of planar metal layer 521 and planar metal layer 699 provides shielding of wireless electromagnetic signals emitted by the third electrically conductive path (such as electrically conductive path 223-P11 and electrically conductive path 223-P12).

FIG. 6B is an example diagram illustrating a side cutaway view of a transformer assembly as discussed herein.

In this example, the metal clip (such as including electrically conductive path 223-P11 and electrically conductive path 223-P12) can be configured to include a metal shield layer 690 enveloping the metal clip (such as a third portion of the third electrically conductive path 123). As shown, the clip (such as including electrically conductive path 223-P11 and electrically conductive path 223-P12) is neither disposed in the first magnetically permeable material 111 nor the second magnetically permeable material 112.

Note that the shielding provided by 690 can be implemented in any of the configurations as discussed herein.

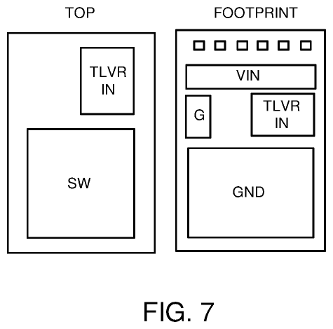

FIG. 7 is an example diagram illustrating of a power stage and TLVR (trans-inductance voltage regulator) connection as discussed herein.

This implementation requires a new dedicated power stage with a TLVR exposed pad on top of its package (assembly 100) and a TLVR pad in its footprint like in the example depicted in FIG. 7.

An advantage of the implementation in FIG. 7 is that the PCB area previously used for the TLVR IN connection is saved enabling more flexibility in the design and to use it for additional components. Moreover, the TLVR conductor manufacturability is greatly simplified as the baseplate of the winding does not require to be bended anymore.

FIG. 8 is an example 3-D diagram illustrating a power converter assembly illustrating flow of current through a series connection of multiple transformer windings as discussed herein. In this example, the assembly 100 includes an interposer 810. The interposer 810 is optional.

The interposer 810 may be disposed between the host substrate 301 layer (such as substrate 301-1 and substrate 301-2) and a combination of the first magnetically permeable material 111 and the second magnetically permeable material 112. Further, the interposer 810 can be configured to provide connectivity (such as circuit path #6) of the electrically conductive path 123-1 (such as circuit path #3) to the electrically conductive path 123-2 (such as circuit path #7). Alternatively, if the interposer 810 is not present in the assembly 100, the substrate 301 (a.k.a., substrate layer) and/or substrate 302 provide connectivity associated with the series circuit path including electrically conductive path 123-1, electrically conductive path 123-2, and so on.

Note that the interposer 810 (such as a PCB) may be soldered to each power stage package through an exposed pad which can be either belonging to an electrically floating net or to a stable potential which is good to shield, in case it is needed, the sensitive gate driving circuitry inside the power stage's package. Such an example implementation may be mainly beneficial when there is the need of shielding such circuitry from the TLVR's noise. The instance of assembly 100 in FIG. 8 includes multiple heat dissipation paths such as respective phase windings (electrically conductive paths 121 and 122) as well as other goes from the exposed pad of the package, through the interposer 810 (such as PCB) and finally through the TLVR windings up to the heatsink (such as surface 321 or corresponding heatsink coupled to surface 321).

In one example, only two TLVR pads are needed on the substrate PCB, giving the designer more flexibility.

The interposer 810 can include additional electrical nets (such as metal circuit paths) as discussed herein. Alternatively, note that any of the connectivity provided by the interposer 810 can be implemented via one or more of the substrate 301 (such as substrate 301-1, substrate 301-2, etc.), substrate 302, etc.

Further in this example of the series circuit path 160 (such as circuit paths 1, 2, 3, 4, 5, 6, 7, 8, 9), flow of current from TLVR1-IN extends along circuit path #1 between the substrate 302 and the interposer 810 or other suitable entity of the assembly 100. The flow of current is then conveyed along the circuit path #2 in the interposer 810 to the axial end E1 of the electrically conductive path 123-1. The circuit path #3 (such as electrically conductive path 123-1) conveys the flow of current from axial end E1 to the axial end E2 of the electrically conductive path 123-1. As previously discussed, the electrically conductive path 123-1 supports conveyance of heat from the one or more of the interposer 810, substrate 301, substrate 302, components associated with assembly 100, etc. Still further, the circuit path #4 such as the electrically conductive element 223-P11 conveys the current to the circuit path #5 such as electrically conductive element 223-P12. The flow of current is then conveyed along the circuit path #6 in the interposer 810 or other suitable entity (such as substrate 302, substrate 301, etc.) to the axial end E3 of the electrically conductive path 123-1. The circuit path #7 (such as electrically conductive path 123-2) conveys the flow of current from axial end E3 to the axial end E4 of the electrically conductive path 123-2. As previously discussed, the electrically conductive path 123-2 supports conveyance of heat from the one or more of the interposer 810, substrate 301, substrate 302, components associated with assembly 100, etc. The circuit path #8 such as the electrically conductive element 223-P21 conveys the current to the circuit path #9 such as electrically conductive element 223-P22. The circuit path #9 conveys the current to a reference voltage node associated with the interposer 810 or through the interposer 810 to the substrate 301 and/or substrate 302.

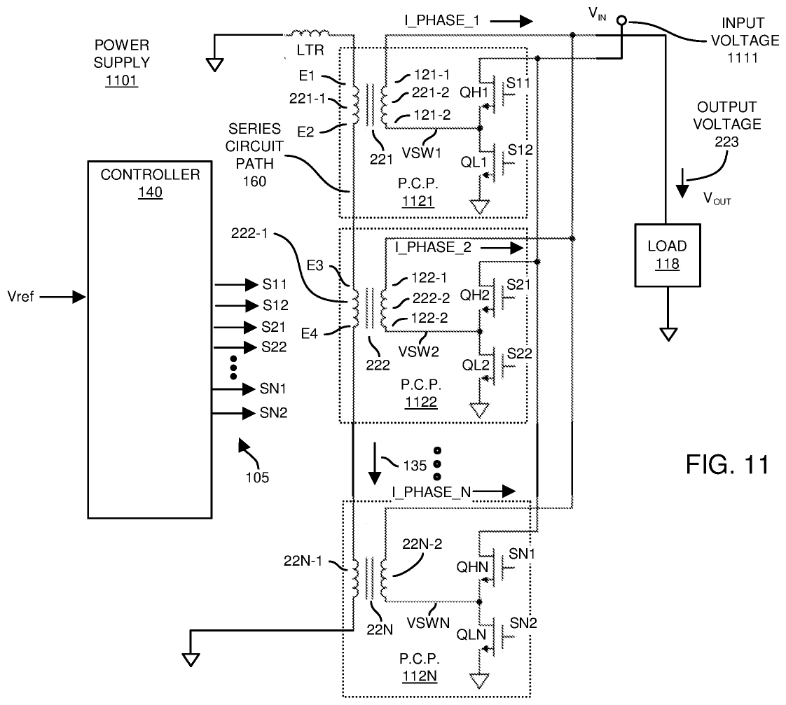

Note further that any of the circuit components in FIG. 11 (such as trans-inductance voltage regulator circuit) can be mounted to the substrate 301-1, substrate 301-2, substrate 301 (if substrate 301-1 and substrate 301-2 are implemented as a single substrate 301), substrate 302, and so on. Switching of the corresponding switches in the trans-inductance voltage regulator circuit is operative to convert a respective input voltage into an output voltage results and corresponding heat at the bottom layer (such as substrate 301, substrate 302, etc.) of the assembly 100. As previously discussed, the electrically conductive paths such as electrically conductive path 121, electrically conductive path 122, electrically conductive path 123-1, electrically conductive path 123-2, circuit path #5, circuit path #9, etc., provide a way in which the corresponding heat flows along the Y-axis to the top side of the assembly 100 such as planar metal layer 321.

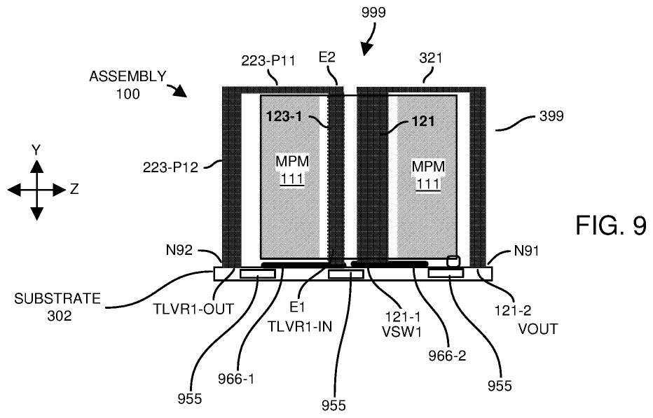

FIG. 9 is an example diagram illustrating implementation of a transformer assembly as discussed herein.

In this implementation, all of the circuit components 955 (such as switches and/or other components associated with control of current through the electrically conductive paths as shown in the trans-inductance voltage regulator circuit of FIG. 11) may be embedded into or one or more surfs of the substrate 302, in which the TLVR net routing is done. The benefit of embedding components in the substrate 302 include: no cost adder for the power stage′ package, reduced PDN for higher efficiency and more height available for the other components (like the magnetics). Additionally, the TLVR windings (such as electrically conductive path 123-1, electrically conductive path 123-2, etc.) can be further simplified without requiring any baseplate for the connection to the substrate 302 (such as PCB).

As previously discussed, each of the different electrically conductive paths as discussed herein can be configured to carry heat to the substrate 301, substrate 302, etc. In this example, the switches and corresponding controller (such as components 955) associated with the trans-inductance voltage regulator circuit (such as FIG. 11) and corresponding power converter assembly 100 are disposed on or embedded within the substrate 302.

Note that the substrate 302 can include a respective planar metal layer 966-1 to provide respective flow of heat associated with the substrate 302 and components 955 (any components associated with trans-inductance voltage regulator) to the axial end 121-1, through the electrically conductive path 121 to a corresponding top surface 999 of the assembly 100 for dissipation of heat. Heat may flow in an opposite direction as well. As previously discussed, the assembly 100 can be configured to include a respective heatsink on the top surface of assembly 100. Additionally, substrate 302 can include a respective planar metal layer 966-2 to provide respective flow of heat associated with the substrate 302 and components 955 to the axial end E1, through the electrically conductive path 123-1 to a corresponding top surface 999 of the assembly 100 for dissipation of heat.

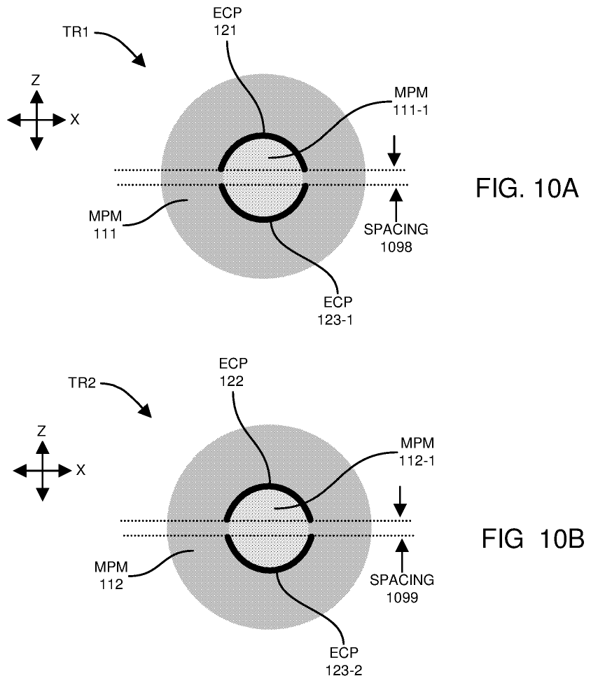

FIG. 10A and FIG. 10B are example cross-section view diagrams illustrating inductive winding associated with a transformer assembly as discussed herein.

Each of the transformers T1, T2, etc., and corresponding electrically conductive paths in the assembly 100 can be configured in any suitable manner.

In this example cross section view of the transformer TR1 in FIG. 10A (such as view in assembly 100 along axis Y to view the electrically conductive path 121 and electrically conductive path 123-1) including an instance of electrically conductive path 121 and an instance of the electrically conductive path 123-1, the electrically conductive path 121 is a curved in which the corresponding concave portion is filled with magnetically permeable material 111-1; the electrically conductive path 123-1 is a curved in which the corresponding concave portion is filled with magnetically permeable material 111-1. The magnetically permeable material 111-1 can be configured to have a different magnetic permeability than magnetically permeable material 111. The curved electrically conductive paths are spaced apart via spacing 1098.

The transformer TR2 can be configured in a similar manner. For example, in this example cross section view of the transformer TR2 of FIG. 10B (such as view in assembly 100 along axis Y to view the electrically conductive path 122 and electrically conductive path 123-2) including an instance of electrically conductive path 122 and an instance of the electrically conductive path 123-2, the electrically conductive path 122 is a curved in which the corresponding concave portion is filled with magnetically permeable material 112-1; the electrically conductive path 123-2 is a curved in which the corresponding concave portion is filled with magnetically permeable material 112-1. The magnetically permeable material 112-1 can be configured to have a different magnetic permeability than magnetically permeable material 112. The curved electrically conductive paths are spaced apart via spacing 1099.

Note that examples as discussed herein can be easily extended to Nph>2 or narrowed to Nph=1.

FIG. 11 is an example diagram illustrating a power supply circuit for implementing any of the transformer assemblies in a trans-inductance voltage regulator as discussed herein.

Note that the Ltr inductor in this example trans-inductance voltage regulator can be used to define the di/dt of the output currents from each of the power converter phases when a transient occurs with respect to the load 118. This inductor Ltr can be either a discrete inductor or implemented through PCB's parasitics and/or the combination of the leakage inductances of the phase transformers.

Further in this example, each of the power converter phases in the power supply 1101 (such as power converter phase 1121, power converter phase 1122, . . . , power converter phase 112N, includes a pair of switches (such as high side switch circuitry and low side switch circuitry) and one or more windings to contribute to generation of the output voltage 223. The controller 140 generates control signals 105 (such as control signals S11, S12, S21, S22, . . . , SN1, and SN2) to regulate generation of a respective output voltage 223 with respect to a setpoint reference voltage Vref.

For example, the power converter phase 1121 of power supply 1101 (such as a trans-inductance voltage regulator) includes transformer 221 (such as TR1 including a combination of electrically conductive path 121 and electrically conductive path 123-1), switch QH1 (such as high side switch circuitry) controlled by signal S11 generated by the controller 140, and switch QL1 (such as low side switch circuitry) controlled by signal S12 generated by controller 140. Switch QH1 is connected in series with switch QL1 between the input voltage Vin 1111 and a ground reference potential. The drain of switch QH1 in this example receives the input voltage 1111; the source of QH1 is connected to the drain of switch QL1 and contributes to producing the output voltage 223; the source of QL1 is connected to ground. The switches QH1 and QL1 and/or controller 140 (such as circuit components) as discussed herein can be disposed on or affixed to any suitable substrate such as substrate 301, substrate 302, interposer 810, etc. The switching of switches and corresponding current flow (such as current I_PHASE_1) outputted from the power converter phase 1121 results in generation of heat that is conveyed along the electrically conductive path 121 and electrically conductive path 123-1 to an appropriate heatsink or top surface of the assembly 100 as previously discussed.

The power converter phase 1122 of power supply 1101 includes transformer 222 (such as transformer TR2 including combination of electrically conductive path 122 and electrically conductive path 123-2), switch QH2 (such as high side switch circuitry) controlled by signal S21 generated by the controller 140 and switch QL2 (such as low side switch circuitry) controlled by signal S22 generated by controller 140. Switch QH2 is connected in series between the input voltage 1111 and a ground reference potential. The drain of switch QH2 receives the input voltage 1111; the source of QH2 is connected to the drain of switch QL2 and contributes to producing the output voltage 223; the source of QL2 is connected to ground. The switches QH2 and QL2 and/or controller 140 (such as circuit components) as discussed herein can be disposed on or affixed to any suitable substrate such as substrate 301, substrate 302, interposer 810, etc. The switching of switches and corresponding current flow (such as current I_PHASE_2) outputted from the power converter phase 1122 results in generation of heat that is conveyed along the electrically conductive path 122 and electrically conductive path 123-2 to an appropriate heatsink as previously discussed.

The power converter phase 112N (nth phase of power supply 1101 such as a trans-inductance voltage regulator) includes transformer 22N (such as combination of electrically conductive path 22N-2 and electrically conductive path 22N-1), switch QHN (such as high side switch circuitry) controlled by signal SN1 generated by the controller 140 and switch QLN (such as low side switch circuitry) controlled by signal SN2 generated by controller 140. Switch QHN is connected in series between the input voltage 1111 and a ground reference. The drain of switch QHN receives the input voltage 1111; the source of QHN is connected to the drain of switch QN1 and contributes to producing the output voltage 223; the source of QN1 is connected to ground. The switches QHN and QLN and/or controller 140 (such as circuit components) as discussed herein can be disposed on or affixed to any suitable substrate such as substrate 301, substrate 302, interposer 810, etc. The switching of switches and corresponding current flow (such as current I_PHASE_N) outputted from the power converter phase 112N results in generation of heat that is conveyed along the electrically conductive path 22N-1 and electrically conductive path 22N-2 to an appropriate heatsink as previously discussed.

In one example, the controller 140 generates the control signals 105 depending on a magnitude of the output voltage 223 with respect to a desired setpoint voltage as in buck converter or other suitable technology. In general, as in a buck converter topology, activation of corresponding high side switch circuitry in a respective power converter phase increases a magnitude of the output voltage 223; activation of the low side switch circuitry results in decreased current to the load from the energy stored in the inductor.

In one example, the windings 123-1, 123-2, . . . 22N-1, are first windings of the multiple power converter phases connected in series in the series circuit path 160 as discussed herein. Each of the multiple power converter phases 1121, 1122, 112N, includes a first winding (such as primary winding) and a second winding (such as secondary winding). In such an example, each of the second windings 121, 122, . . . , 22N-2, of the multiple power converter phases produces, based on control signals from the controller 140, respective phase output current (or voltage) contributing to generation of an output voltage 223 that powers a load 118.

For example, electrically conductive path 121 produces/outputs current I_phase_1; electrically conductive path 122 produces/outputs current I_phase_2; . . . ; electrically conductive path 22N-2 produces/outputs current I_phase_N.

In one example, the low side switch circuitry in a respective phase is activated when the corresponding high side switch circuitry is deactivated. The high side switch circuitry and low side switch circuitry are never activated at the same time. There is a dead time between activating the high side switch circuitry and low side switch circuitry.

In this example, power converter phase 1121 represents phase_1 supplying current to the load 118; power converter phase 1122 represents phase_2 supplying current to the load 118; . . . ; power converter phase 112N represents phase_N supplying current to the load 118.

Accordingly, the series circuit path 160 associated with the power supply 1101 (such as trans-inductance voltage regulator) can be configured to include series circuit path 160 comprising multiple electrically conductive paths (123-1, 123-2, etc.), each of which is implemented as a trans-inductance voltage regulator winding. The first switch circuitry in the power converter phase 1121 such as QH1 and QL1 coupled to the axial end 121-2 of the first electrically conductive path 121 control a magnitude of first current I_PHASE_1 through the first electrically conductive path 121 to the load 118. The node coupling the electrically conductive path 121, switch QH1, and switch QL1 is voltage VSW1.

The second switch circuitry in the power converter phase 1122 such as QH2 and QL2 coupled to the axial end 122-2 of the first electrically conductive path 122 control a magnitude of first current I_PHASE_2 through the electrically conductive path 122 to the load 118. The node coupling the electrically conductive path 122, switch QH2, and switch QL2 is voltage VSW2, and so on.

Accordingly, the second axial end 121-1 of the first electrically conductive path 121 is directly connected to the second axial end 122-1 of the second electrically conductive path 122 to produce an output voltage 223.

As previously discussed, any of the circuit components such as switches QH1, QL1, QH2, QL2, . . . , controller 140 can be configured to be directly coupled to one or more surfaces of or embedded in any of the circuit boards or substrates as discussed herein.

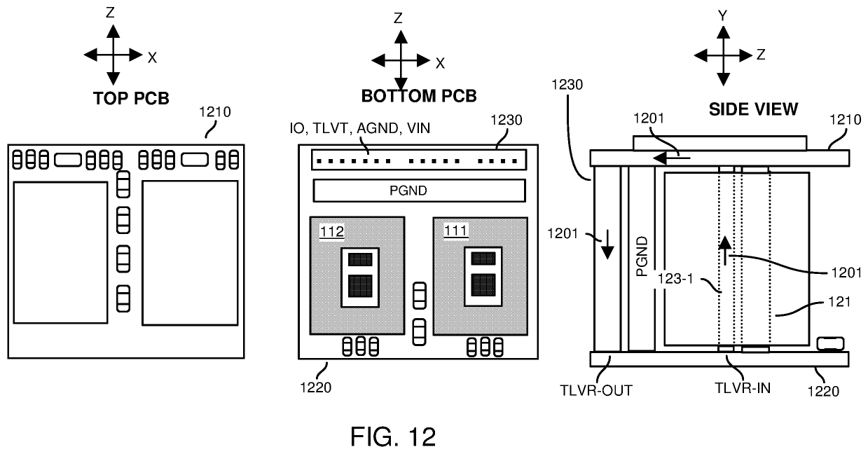

FIG. 12 is an example diagram illustrating different views of a transformer assembly as discussed herein.

In this example, the bottom PCB (such as substrate 1220) acts as interface with the customer's motherboard, and accommodates Vin, Vout and GND nets as well as the power stage's I/O signals and TLVR I/O nets.

The top PCB such as substrate 1210 hosts the power stages and corresponding components associated with the power supply 1101, including their relative auxiliary capacitors/resistors and some input capacitors.

The vertical substrate 1230 (such as a PCB) is implemented to route signals and voltages from the bottom substrate 1220 to the top substrate 1210 such as the power stage's I/O signals, the input power VIN, the TLVRs nets and optionally an analog ground net (AGND).

It is noted that PGND circuit path can be a solid piece of metal material able to carry high currents. Given that the current flowing into or through the PGND path is mainly dominated by a DC component, the PGND circuit path helps in reducing the conduction loss, boosting the efficiency and so mitigating partly the typical drawback of a power stage cooled module. Optionally, the VIN input power path can be implemented thorough an external copper block in a similar manner such as extending from the substrate 1210 to the substrate 1220.

However, in certain cases, it may be desirable to include the PGND power path in the vertical substrate 1230. The adoption of the inductive components (electrically conductive paths) as discussed herein enables the module to be highly scalable: it will sufficient to change the magnetic core height to meet new module's height and/or inductance requirements.

The proposed TLVR (trans-inductance voltage regulator) routing as depicted herein (such as through electrically conductive path 123-1, substrate 1210, and substrate 1201) supports current flow 1201. The input pad can be configured to lie on the bottom substrate 1220 and may be connected to the straight single-turn TLVR winding such as electrically conductive path 123-1, conveying the current 1201 up to the top substrate 1210.

To properly route such current 1201 to the electrically conductive path (such as adjacent TLVR winding), the TLVR net is firstly routed into the top substrate 1210 and then to the vertical substrate 1230 through which the TLVR current 1201 can flow down again to the bottom PCB (substrate 1220) and finally fed into the adjacent phase's TLVR winding in a manner as previously discussed. The phase winding (such as electrically conductive path 121) may provide a minimum power distribution network yielding to a reduction of the conduction loss and efficiency increase.

It may be noted that given it's electrical task, the TLVR windings such as electrically conductive paths 123-1, 123-2, and so on, may be a strong noise source due to its rapidly varying AC current through the corresponding series circuit path 160. This aspect shows another fundamental benefit of the proposed structure: the TLVR connectivity or net is completely enclosed into the magnetic core (magnetically permeable material 110) and the three PCBs (substrate 1210, 1220, and 1230); therefore wireless generated noise has no exit to the external environment with respect to the assembly 100, including the gate driving ICs of the power stages. This makes this solution advantageously suitable for noise sensitive applications.

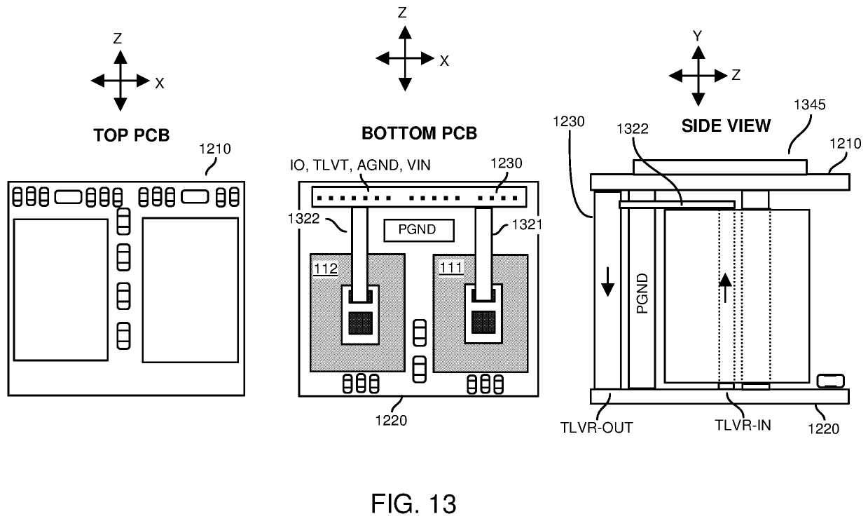

In a case it is desirable to simplify the layout of the top substrate 1210 and/or of the vertical substrate 1230, note that it is possible to have the trans-inductance voltage regulator clip routing towards the bottom substrate 1220 through an external copper clip like shown in FIG. 13.

FIG. 13 is an example diagram illustrating different views of a transformer assembly as discussed herein.

In this example the TLVR windings are routed to the vertical substrate (PCB) through external clips (such as electrically conductive paths 1321 and 1322) rather than through the top substrate 1210 (PCB) which can have a simpler layout than as previously discussed. This way, the TLVR windings are not connected on the power stage substrate 1220, which has the benefit of preventing the risk of noise injection toward the driver IC inside the power stages.

Thus, in this example, a portion of the magnetically permeable material 111 is disposed between the electrically conductive path 1321 and the substrate 1220. A portion of the magnetically permeable material 112 is disposed between the electrically conductive path 1322 and the substrate 1220. A heatsink 1345 coupled to the substrate 1210 can be configured to provide electromagnetic shielding of noise emitted by the trans-inductance voltage regulator windings or return paths such as electrically conductive path 1321 and electrically conductive path 1322.

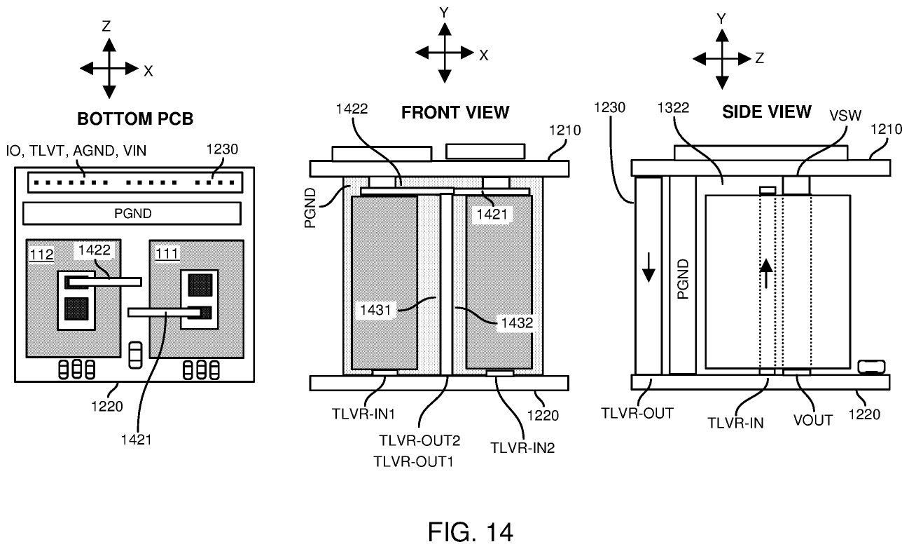

FIG. 14 is an example diagram illustrating different views of a transformer assembly as discussed herein.

In this example, the TLVR routing to the bottom substrate 1220 is done entirely through respective external clips such as electrically conductive paths 1421 and 1422, without the need of a dedicated net inside the top substrate 1210 and vertical substrate 1230. However, also in these examples, the TLVR windings are well shielded from the outside environments through the substrates and the magnetic cores (such as magnetically permeable material 111 and magnetically permeable material 112).

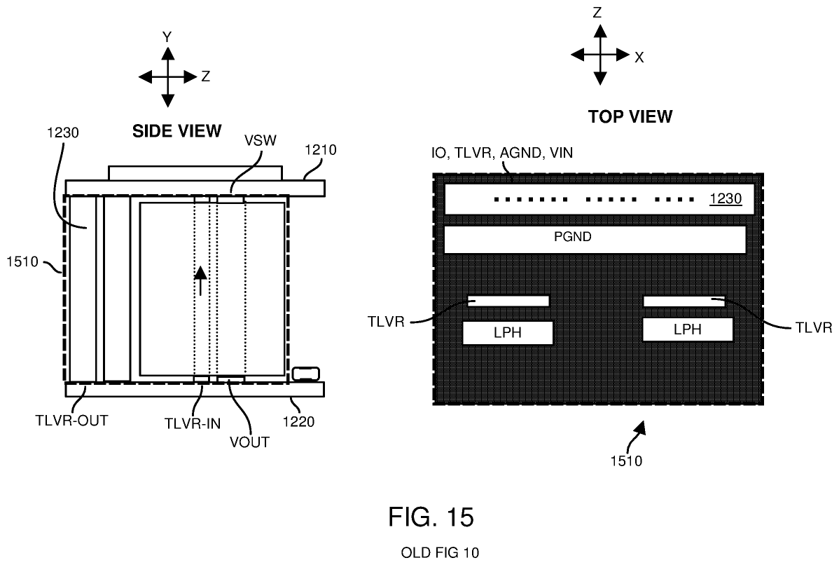

In order to simplify the module assembly 100 and fabricate in mass production, the set of inductor, vertical PCB and GND copper blocks can be over-molded into one single pick and place component (such as assembly 1510) as depicted in FIG. 15. In such an instance, the portions of the electrically conductive paths 1431 and 1432 (vertical portions) reside between the first magnetically permeable material and the second magnetically permeable material.

FIG. 15 is an example diagram illustrating an over-mold transformer assembly as discussed herein.

As shown, the assembly 100 or portions thereof can be implemented in an over-mold assembly 1510. Over-mold assembly 1510 includes a first circuit board such as substrate 1210, PGND electrically conductive path, the first magnetically permeable material 111, the second magnetically permeable material 112, the first electrically conductive path 121, electrically conductive path 123-1, electrically conductive path 122, and the electrically conductive path 123-2. The over-mold assembly 1510 can be configured to reside between circuit board such as substrate 1210 and circuit board such as substrate 1220. The circuit board 1230 in the over-mold assembly 1510 provides connectivity between the substrate 1210 (circuit board) and the substrate 1220 (circuit board). The over-mold assembly 1510 can be configured to include the first magnetically permeable material 111 and the second magnetically permeable material 112 resides between substrate 1210 and substrate 1220.

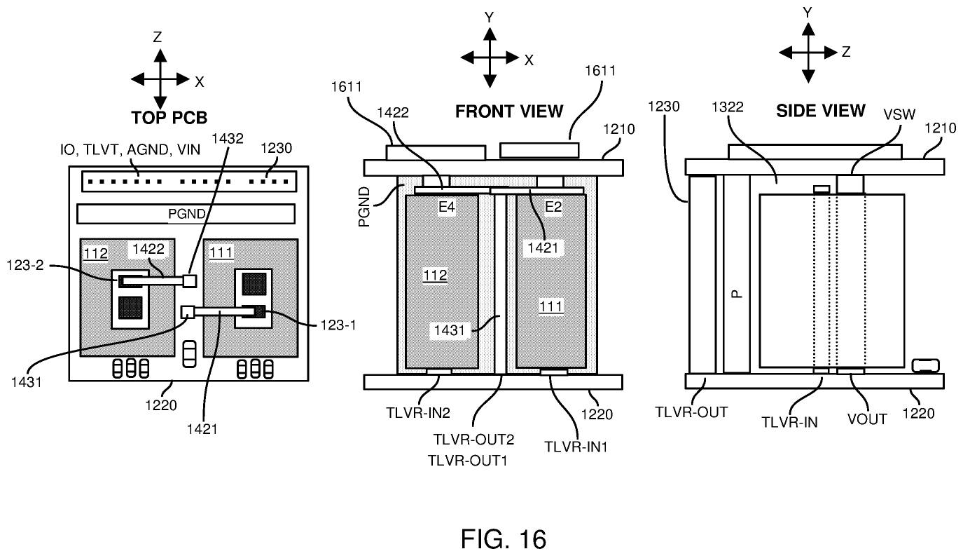

FIG. 16 is an example diagram illustrating different views of a transformer assembly as discussed herein.

As previously discussed, each of the different implementations as discussed herein can be configured to include components 1611 in a power stage with (where components include 1611 such as switches, controller, etc., in FIG. 11 and other FIGS.), which are directly chip embedded inside or on one or more surfaces of the top substrate 1210 as shown in FIG. 16.

In this example, the axial end E2 of the electrically conductive path 123-1 is directly coupled to the electrically conductive path 1421; the axial end E4 of the electrically conductive path 123-2 is directly coupled to the electrically conductive path 1422. The combination of electrically conductive path 1421 and 1431 provide a path from the top of the electrically conductive path 123-1 to the substrate 1220; the combination of electrically conductive path 1422 and 1432 provide a path from the top of the electrically conductive path 123-2 to the substrate 1220.

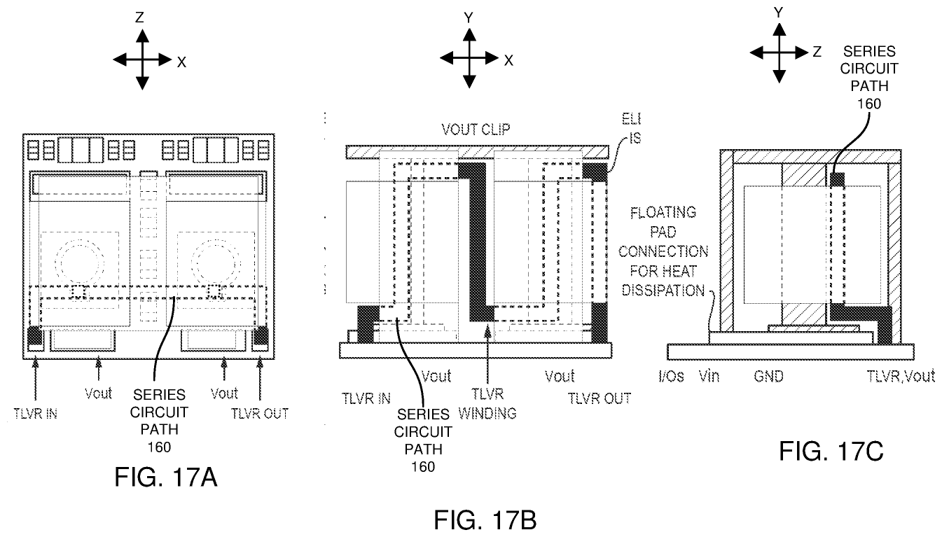

FIGS. 17A, 17B, and 17C are example diagrams illustrating different views of providing serial connecting through multiple windings of multiple transformers as discussed herein.

In this example, the TLVR windings are implemented with multiple time bended copper wire for ease of manufacturability.

The TLVR windings are shielded by Vout clip for low noise radiation

The TLVR windings are electrically isolated.

Only stable Vout clip exposed to customer's heatsink

Floating pad thermal dissipation can be achieved through stable potential Vout clip.

No need for re-routing of TL VR net connects into the PCB for lowest noise injection towards power stage's I/Os.

TLVR windings are optionally done with litz wire for reduced ACR.

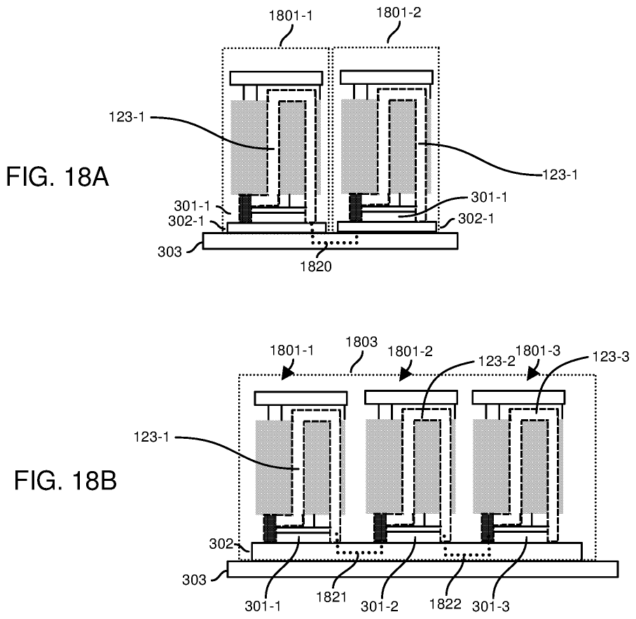

FIG. 18A is an example diagram of multiple individual assemblies mounted on a respective host substrate as discussed herein.

In this example, the assembly 1801-1 and assembly 1801-2 are identical. The assembly 1801-1 includes a single phase such as first electrically conductive path 121-1 disposed in parallel with an electrically conductive path 122 in respective magnetically permeable material in a manner as previously discussed. A customer may buy any number of instances of these individual assemblies 1801-1, 1801-2, etc., and mount them on a respective host substrate 303 as shown. The electrically conductive path 1820 provides circuit path connectivity of the respective electrically conductive paths 123-1 and 123-2 (such as trans-inductance voltage regulator paths) in series.

FIG. 18B is an example diagram of the multiple instances of sub-assemblies forming a single multi-phase assembly mounted on a respective host substrate as discussed herein.

In this example, the assembly 1803 includes assembly 1801-1, assembly 1801-2, and assembly 1801-3, each of which is identical. The assembly 1801-1 includes a single phase such as first electrically conductive path 121-1 disposed in parallel with an electrically conductive path 122 in respective magnetically permeable material in a manner as previously discussed. In this example, the customer buys a single assembly 1803 including any number of instances of these individual assemblies 1801-1, 1801-2, etc., on the substrate 302 of the assembly 1803. As previously discussed, the electrically conductive paths 123-1, 123-2, 123-3, etc., provide serial connectivity of the TLVR windings (electrically conductive paths) through the assembly 1803. The customer mounts the assembly 1803 on the respective host substrate 303 as shown. The electrically conductive paths 1821, 1822, etc., provide circuit path connectivity of the respective electrically conductive paths 123-1 and 123-2 (such as trans-inductance voltage regulator paths) in series amongst the assemblies 1801-1, 1801-2, etc. The circuit paths 1821, 1822, etc., may reside in or on the substrate 302 and/or in or on the substrate 303.

Note again that techniques herein are well suited for use in circuit assembly applications such as those providing power delivery to one or more loads. However, it should be noted that the disclosure of matter herein is not limited to use in such applications and that the techniques discussed herein are well suited for other applications as well.

While this invention has been particularly shown and described with references to preferred aspects thereof, it will be understood by those skilled in the art that various changes in form and details may be made therein without departing from the spirit and scope of the present application as defined by the appended claims. Such variations are intended to be covered by the scope of this present application. As such, the foregoing description in the present disclosure is not intended to be limiting. Rather, any limitations to the invention are presented in the following claims.

1. An apparatus comprising:
a first electrically conductive path extending through first magnetically permeable material; and
a second electrically conductive path extending through the first magnetically permeable material, the first electrically conductive path disposed alongside and in parallel with the second electrically conductive path through the first magnetically permeable material.

2. The apparatus as in claim 1 further comprising:
an assembly comprising:
the first electrically conductive path;
the second electrically conductive path;
a first substrate;
wherein a first axial end of the first electrically conductive path is directly coupled to a first node of the first substrate, the first electrically conductive path providing a first heat dissipation path between a second axial end of the first electrically conductive path and the first node;
wherein a first axial end of the second electrically conductive path is directly coupled to a second node of the first substrate, the second electrically conductive path providing a second heat dissipation path between a second axial end of the second electrically conductive path and the second node;
wherein an axial length of the first electrically conductive path extends substantially orthogonal to a planar surface of the first substrate; and
wherein an axial length of the second electrically conductive path extends substantially orthogonal to the planar surface of the first substrate.

3. The apparatus as in claim 2 further comprising:
electronic circuitry embedded in the first substrate, the electronic circuitry controlling conveyance of current through the first electrically conductive path.

4. The apparatus as in claim 2 further comprising:
electronic circuitry affixed to the first substrate, the electronic circuitry controlling conveyance of current through the first electrically conductive path.

5. The apparatus as in claim 2, wherein the assembly further includes:
a third electrically conductive path extending through second magnetically permeable material;
a fourth electrically conductive path extending through the second magnetically permeable material, the third electrically conductive path disposed alongside and in parallel with the fourth electrically conductive path through the second magnetically permeable material;
wherein a first axial end of the third electrically conductive path is directly coupled to a third node of the first substrate, the third electrically conductive path providing a third heat dissipation path between a second axial end of the third electrically conductive path and the third node;
wherein a first axial end of the fourth electrically conductive path is directly coupled to a fourth node of the first substrate, the fourth electrically conductive path providing a fourth heat dissipation path between a second axial end of the fourth electrically conductive path and the fourth node;
wherein an axial length of the third electrically conductive path extends substantially orthogonal to the planar surface of the first substrate; and
wherein an axial length of the fourth electrically conductive path extends substantially orthogonal to the planar surface of the first substrate.

6. The apparatus as in claim 5 further comprising:
an electrically conductive element providing connectivity between the second node and the fourth node, the electrically conductive element connecting the second electrically conductive path and the fourth electrically conductive path in series.

7. The apparatus as in claim 6, wherein the electrically conductive element is affixed to the first substrate.

8. The apparatus as in claim 1 further comprising:
a first assembly comprising:
a first substrate;
the first electrically conductive path;
the second electrically conductive path;
wherein a first axial end of the first electrically conductive path is directly coupled to a first node of the first substrate, the first electrically conductive path providing a first heat dissipation path between a second axial end of the first electrically conductive path and the first node;
wherein a first axial end of the second electrically conductive path is directly coupled to a second node of the first substrate, the second electrically conductive path providing a second heat dissipation path between a second axial end of the second electrically conductive path and the second node;
wherein an axial length of the first electrically conductive path extends substantially orthogonal to a planar surface of the first substrate; and
wherein an axial length of the second electrically conductive path extends substantially orthogonal to the planar surface of the first substrate;
a second assembly comprising:
a second substrate;
a third electrically conductive path extending through second magnetically permeable material;
a fourth electrically conductive path extending through the second magnetically permeable material, the third electrically conductive path disposed alongside and in parallel with the fourth electrically conductive path through the second magnetically permeable material;
wherein a first axial end of the third electrically conductive path is directly coupled to a first node of the second substrate, the third electrically conductive path providing a third heat dissipation path between a second axial end of the third electrically conductive path and the first node of the second substrate;
wherein a first axial end of the fourth electrically conductive path is directly coupled to a second node of the second substrate, the fourth electrically conductive path providing a fourth heat dissipation path between a second axial end of the fourth electrically conductive path and the second node of the second substrate;
wherein an axial length of the third electrically conductive path extends substantially orthogonal to a planar surface of the second substrate; and
wherein an axial length of the fourth electrically conductive path extends substantially orthogonal to the planar surface of the second substrate.

9. The apparatus as in claim 8 further comprising:
a third substrate; and
wherein the first substrate and the second substrate are affixed to the third substrate.

10. The apparatus as in claim 9 further comprising:
an electrically conductive element providing serial connectivity of the second electrically conductive path and the fourth electrically conductive path; and
wherein the electrically conductive element is affixed to the third substrate.

11. The apparatus as in claim 1 further comprising:
a third electrically conductive path;
a fourth electrically conductive path, the combination of the third electrically conductive path and the fourth electrically conductive path extending through second magnetically permeable material, the third electrically conductive path disposed alongside and in parallel with the fourth electrically conductive path in the second magnetically permeable material; and
a circuit path serially connecting the second electrically conductive path and the fourth electrically conductive path.

12. The apparatus as in claim 11, wherein a combination of the first electrically conductive path and the second electrically conductive path is a first transformer in which the first electrically conductive path is inductively coupled to the second electrically conductive path; and
wherein a combination of the third electrically conductive path and the fourth electrically conductive path is a second transformer in which the third electrically conductive path is inductively coupled to the fourth electrically conductive path.

13. The apparatus as in claim 12, wherein a portion of the first magnetically permeable material is absent from a first volume between the first electrically conductive path and the second electrically conductive path; and
wherein a portion of the second magnetically permeable material is absent from a second volume between the third electrically conductive path and the fourth electrically conductive path.

14. The apparatus as in claim 11 further comprising:
first switch circuitry coupled to a first axial end of the first electrically conductive path, the first switch circuitry operative to control a magnitude of first current through the first electrically conductive path; and
second switch circuitry coupled to a first axial end of the third electrically conductive path, the second switch circuitry operative to control a magnitude of second current through the third electrically conductive path.

15. The apparatus as in claim 14, wherein control of the first switch circuitry is operative to produce a first output current outputted from a second axial end of the first electrically conductive path; and
wherein control of the second circuitry is operative to produce a second output current outputted from a second axial end of the third electrically conductive path.

16. The apparatus as in claim 15, wherein the second axial end of the first electrically conductive path is directly connected to the second axial end of the third electrically conductive path to collectively produce an output voltage.

17. The apparatus as in claim 11, wherein the circuit path including the second electrically conductive path and the fourth electrically conductive path in series is configured to convey only alternating current.

18. The apparatus as in claim 17, wherein a first axial end of the circuit path and a second axial end of the circuit path are both directly coupled to a voltage reference.

19. The apparatus as in claim 11 further comprising:
a substrate;
a first axial end of the first electrically conductive path being directly coupled to a first node of the substrate, the first electrically conductive path providing a first heat dissipation path between a second axial end of the first second electrically conductive path and the first node; and
a first axial end of the third electrically conductive path being directly coupled to a second node of the substrate, the second electrically conductive path providing a second heat dissipation path between a second axial end of the third electrically conductive path and the second node.

20. The apparatus as in claim 19, wherein an axial length of the first electrically conductive path extends substantially orthogonal to a planar surface of the substrate; and
wherein an axial length of the third electrically conductive path extends substantially orthogonal to the planar surface of the substrate.

21-30. (canceled)
